(19) United States
(12) Patent Application Publication
(10) Pub. No.: US 2025/0363254 A1
(43) Pub. Date: Nov. 27, 2025

(54) GEOMETRIC PROMPTING FOR CONTROLLING CAD GENERATION

(71) Applicant: AUTODESK, INC., San Francisco, CA (US)

(72) Inventors: Joseph George LAMBOURNE, London (GB); Karl D.D. WILLIS, San Francisco, CA (US); Longfei ZHANG, Shanghai (CN); Iain HENLEY, Essex (GB); Surya PRERAPA, Milton Keynes (GB)

(21) Appl. No.: 18/670,635

(22) Filed: May 21, 2024

(51) Int. Cl. G06F 30/12; G06F 30/20

(52) U.S. Cl. CPC G06F 30/12; G06F 30/20

(57) ABSTRACT

Various embodiments set forth a techniques for generating computer-aided design (CAD) models that includes receiving a plurality of inputs via a user interface, generating a plurality of geometric prompts based on the plurality of inputs, executing a trained machine-learning model on the geometric prompts to generate CAD data, and generating at least one CAD model based on the CAD data. Advantageously, the disclosed techniques can substantially facilitate the overall process of designing CAD objects and CAD models of differing levels of complexity, thereby increasing the accessibility of CAD software and applications to a wider array of users with differing skill sets.

### BACKGROUND

### Field of the Various Embodiments

The contemplated embodiments relate generally to computer science and machine learning and, more specifically, to geometric prompting for controlling computer-aided design generation.

### Description of the Related Art

Computer-Aided Design (CAD) refers generally to the use of computer software to facilitate the creation, modification, analysis, or optimization of a design. CAD software is used in numerous fields, such as mechanical design, electrical design, architectural design, civil engineering, and industrial design, to facilitate the design process. Using CAD software in the design process has many advantages, including simplifying the generation and modification of designs during the design process, the ability to create more accurate and detailed designs, and improving the ability to collaborate through digital files that can be easily shared among users. Some important functionalities of CAD software include two-dimensional (2D) drafting, three-dimensional (3D) modeling, and simulation. 2D drafting includes creating detailed 2D drawings that can include dimensions, notes, and symbols. 3D modeling entails generating 3D models of physical components that can be rotated and viewed from different angles, which makes visualizing designs easier. Simulation allows designers to test the behavior of a design under various conditions, such as increased loads, stresses, and heat.

Despite the above advantages, CAD software has several drawbacks. First, using CAD software can be challenging, especially for beginners, due to the complexity of the software. For example, proficiently using some CAD applications requires knowledge of thousands of different instructions and hundreds of different features and functions. Second, to generate designs that are practical for real-world applications, users have to understand the engineering concepts relevant to their designs. Understanding engineering sometimes can require knowledge of advanced mathematics and physics. For example, knowing how forces are distributed within a given structure may be essential for certain types of designs. Third, users have to understand design and the overall design process to be able to fully explore the design space and develop optimized designs. There is a balance between the hard and fast rules of engineering and the creative and aesthetic aspects of design that can take years of practice to develop. For these reasons and others, developing a proficiency with CAD software typically requires long periods of study and practice, and even experienced users oftentimes discover new tools in a CAD application to use or more efficient ways to approach different types of designs.

As the forgoing illustrates, what is needed in the art are more effective ways to generate designs when using CAD applications.

### SUMMARY

One embodiment of the present disclosure sets forth a computer implemented method for generating CAD models. The method includes generating a plurality of geometric prompts based on a plurality of inputs, executing a trained machine-learning model on the geometric prompts to generate CAD data, and generating at least one CAD model based on the CAD data.

One technical advantage of the disclosed techniques relative to the prior art is that the disclosed techniques can substantially facilitate the overall process of designing CAD objects and CAD models of differing levels of complexity, thereby increasing the accessibility of CAD software and applications to a wider array of users with differing skill sets. With the disclosed technique, users can express complex CAD object or CAD models using a few simple control parameters without having to learn the intricacies of CAD software or a CAD application. Another technical advantage of the disclosed techniques is that the disclosed techniques leverage a machine learning model that is trained using a vast number of previous CAD objects and CAD models. The trained model is able to generate the commands associated with optimized and creative CAD objects and CAD models from a few simple control parameters, which removes the burdens of the conventional design process and conventional CAD software and applications from users. These technical advantages provide one or more technological improvements over prior art approaches.

### BRIEF DESCRIPTION OF THE DRAWINGS

So that the manner in which the above recited features of the various embodiments can be understood in detail, a more particular description of the inventive concepts, briefly summarized above, may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 illustrates a block diagram of a computer-based system configured to implement one or more aspects of the various embodiments;

FIG. 2 is a more detailed illustration of the data collector engine of FIG. 1, according to various embodiments;

FIG. 3 is a more detailed illustration of the CAD generation application of FIG. 1, according to various embodiments;

FIG. 4 illustrates exemplary CAD models generated by the CAD generation application of FIG. 1, according to various embodiments;

FIG. 5 is a flow diagram of method steps for generating CAD models, according to various embodiments;

FIG. 6 is a flow diagram of method steps for training CAD data generator 148, according to various embodiments;

FIG. 7 is a more detailed illustration of a computing device that is configured to implement one or more aspects of the various embodiments.

### DETAILED DESCRIPTION

In the following description, numerous specific details are set forth to provide a more thorough understanding of the various embodiments. However, it will be apparent to one skilled in the art that the inventive concepts may be practiced without one or more of these specific details.

### System Overview

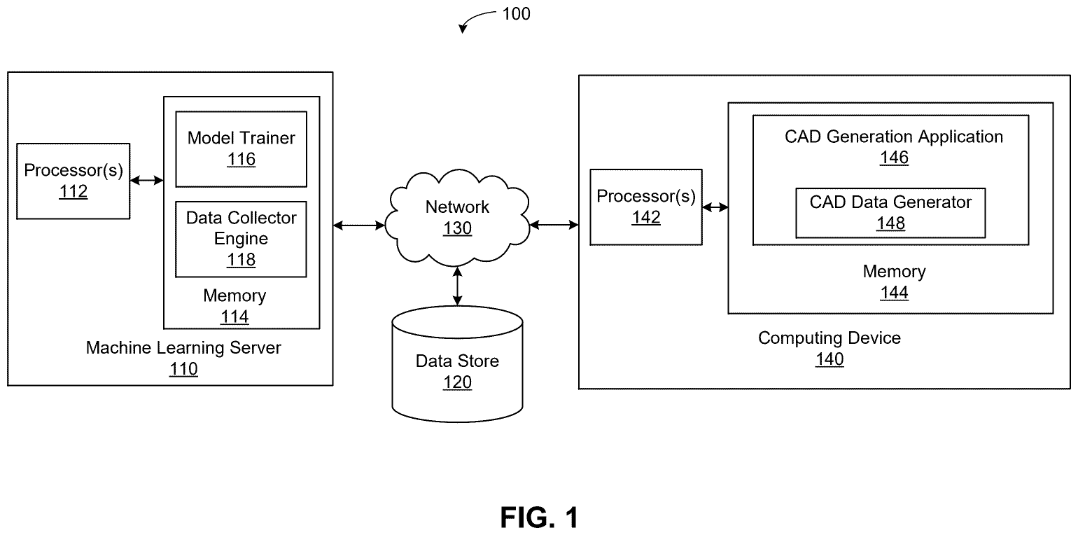

FIG. 1 illustrates a block diagram of a computer-based system 100 configured to implement one or more aspects of the various embodiments. As shown, the system 100 includes a machine learning server 110, a data store 120, and a computing device 140 in communication over a network 130, which can be a wide area network (WAN) such as the Internet, a local area network (LAN), a cellular network, and/or any other suitable network.

The machine learning server 110 includes, without limitation, processor(s) 112 and a memory 114. The processor(s) 112 receive user input from input devices, such as a keyboard or a mouse. In operation, the one or more processors 112 may include one or more primary processors that control and coordinate the operations of the other system components within the machine learning server 110. In particular, the processor(s) 112 can issue commands that control the operation of one or more graphics processing units (GPUs) (not shown) and/or other parallel processing circuitry (e.g., parallel processing units, deep learning accelerators, etc.) that incorporates circuitry optimized for graphics and video processing, including, for example, video output circuitry. The GPU(s) can deliver pixels to a display device that can be any conventional cathode ray tube, liquid crystal display, light-emitting diode display, and/or the like.

The system memory 114 of the machine learning server 110 stores content, such as software applications and data, for use by the processor(s) 112 and the GPU(s) and/or other processing units. The system memory 114 can be any type of memory capable of storing data and software applications, such as a random-access memory (RAM), a read-only memory (ROM), an erasable programmable read-only memory (EPROM or Flash ROM), or any suitable combination of the foregoing. In some embodiments, a storage (not shown) can supplement or replace the system memory 114. The storage can include any number and type of external memories that are accessible to processor 112 and/or the GPU. For example, and without limitation, the storage can include a Secure Digital Card, an external Flash memory, a portable compact disc read-only memory (CD-ROM), an optical storage device, a magnetic storage device, and/or any suitable combination of the foregoing.

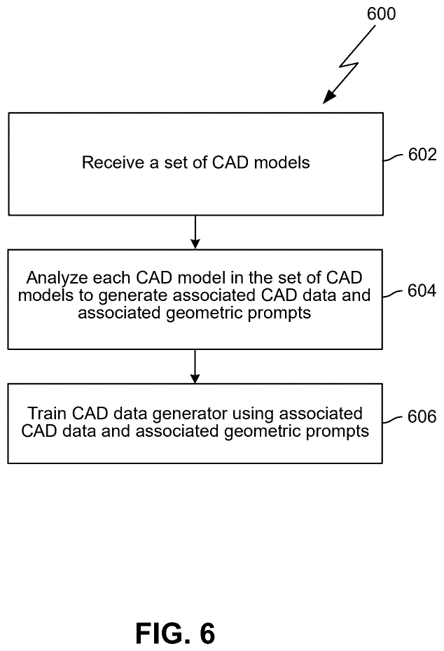

As also shown, memory 114 includes a model trainer 116 and a data collector engine 118. Model trainer 116 is configured to train a CAD data generator 148 residing within a CAD generation application 146 that executes on a computing device 140. In various embodiments, model trainer 116 can implement any technically feasible machine learning model, including, but not limited to, neural networks, decision trees, support vector machines, and ensemble techniques. More generally, the various embodiments extend to any technically feasible generative model architecture. In operation, model trainer 116 can dynamically adjust training parameters and methodologies by incorporating a feedback loop that leverages real-time analysis of any performance metric, such as precision, recall, and loss functions. Model trainer 116 makes adjustments to optimize outputs and learned outcomes. These adjustments can include, without limitation, modifications to learning rates, model architectures, and data processing techniques. In some embodiments, model trainer 116 uses one or more data preprocessors that addresses common issues such as imbalanced datasets, missing values, and noise, thereby ensuring that the data fed into the model is clean, relevant, and representative of the problem space. In various embodiments, model trainer 116 uses data augmentation techniques, which artificially expand the training dataset to improve the model's generalization capabilities, and tailored adjustments to the data. These features are examples only and are not meant in any way to limit the scope or functionality of model trainer 116. The operations invoked by model trainer 116 when training CAD data generator 148 are described in greater detail below in conjunction with FIG. 6.

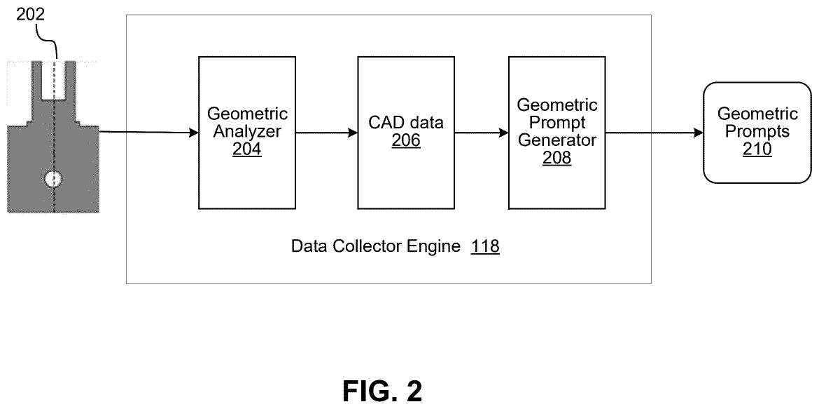

Data collector engine 118 receives a set of two-dimensional CAD profiles or three-dimensional boundary representation models from data store 120 and converts the CAD profiles or boundary representation models into geometric prompts. As used herein, “CAD models” refers to both two-dimensional CAD profiles and three-dimensional boundary representation models. Data collector engine 118 first generates the CAD data 206 by analyzing the geometries of the provided CAD models and then determines what geometric prompts correspond to the CAD model geometries. In various embodiments, data collector engine 118 may receive CAD models from other data storage systems, like a cloud storage, NAS drive, or a network storage connected to the machine learning server 110. Model trainer 116 receives the CAD data 206 and associated geometric prompts from data collector engine 118 and uses those CAD data 206 and associated geometric prompts in training CAD data generator 148. The operations invoked by data collector engine 118 when generating training data are discussed in greater detail below in conjunction with FIG. 2.

The machine learning server 110 shown herein is for illustrative purposes only, and variations and modifications are possible without departing from the scope of the present disclosure. For example, the number of processors 112, the number of GPUs and/or other processing unit types, the number of system memories 114, and/or the number of applications included in the system memory 114 can be modified as desired. Further, the connection topology between the various units in FIG. 1 can be modified as desired. In some embodiments, any combination of the processor(s) 112, the system memory 114, and/or GPU(s) can be included in and/or replaced with any type of virtual computing system, distributed computing system, and/or cloud computing environment, such as a public, private, or a hybrid cloud system.

The computing device 140 includes, without limitation, processor(s) 142 and a memory 144. Processor(s) 142 receive user input from input devices, such as a keyboard or a mouse. Similar to processor(s) 112 of machine learning server 110, in some embodiments, processor(s) 142 may include one or more primary processors that control and coordinate the operations of the other system components within the computing device 140. In particular, the processor(s) 142 can issue commands that control the operation of one or more graphics processing units (GPUs) (not shown) and/or other parallel processing circuitry (e.g., parallel processing units, deep learning accelerators, etc.) that incorporates circuitry optimized for graphics and video processing, including, for example, video output circuitry. The GPU(s) can deliver pixels to a display device that can be any conventional cathode ray tube, liquid crystal display, light-emitting diode display, and/or the like.

Similar to system memory 114 of machine learning server 110, system memory 144 of computing device 140 stores content, such as software applications and data, for use by the processor(s) 142 and the GPU(s) and/or other processing units. The system memory 144 can be any type of memory capable of storing data and software applications, such as a random-access memory (RAM), a read-only memory (ROM), an erasable programmable read-only memory (EPROM or Flash ROM), or any suitable combination of the foregoing. In some embodiments, a storage (not shown) can supplement or replace the system memory 144. The storage can include any number and type of external memories that are accessible to processor 142 and/or the GPU. For example, and without limitation, the storage can include a Secure Digital Card, an external Flash memory, a portable compact disc read-only memory (CD-ROM), an optical storage device, a magnetic storage device, and/or any suitable combination of the foregoing.

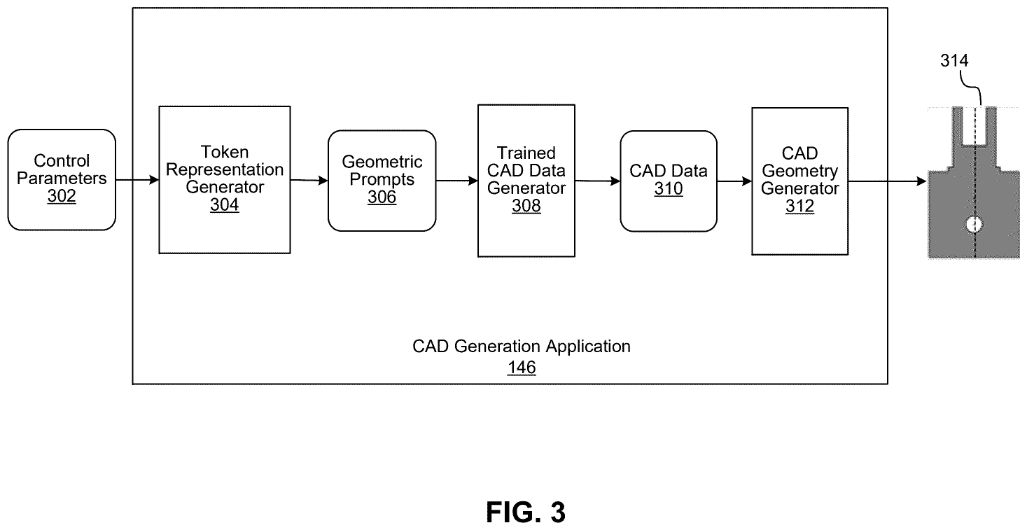

As also shown, system memory 142 includes a CAD generation application 146 that generates CAD models using control parameters provided by the user through a user interface (not shown). More specifically, in operation, a user defines the shape of CAD object using one or more control parameters that the user inputs into CAD generation application 146 via the user interface. CAD generation application 146 then translates those control parameters into geometric prompts via a token representation generator (not shown). In other embodiments, stick models representing linkage designs and assembly interface specifications may be used to define the geometric prompts. CAD generation application 146 includes CAD data generator 148 that receives geometric prompts and generates corresponding Domain Specific Language (DSL) commands. CAD generation application 146 subsequently generates CAD models based on the DSL commands. CAD data generator 148 can be any type of technically-feasible machine learning model. For example, in various embodiments, CAD data generator 148 may be an auto-regressive model, such as a decoder-only transformer, a diffusion model, or a combination of encoder transformer and diffusion model where the transformer encoder output is fed into the diffusion model via cross attention. The generated CAD models comprise the output of CAD generation application 146. The operations invoked by CAD generation application 146 when generating CAD models are described in greater detail below in conjunction with FIG. 3.

Data store 120 provides non-volatile storage for applications and data in machine learning server 110 and computing device 140. For example, and without limitation, training data, trained (or deployed) machine learning models and/or application data, including the CAD data generator 148, may be stored in the data store 120. In some embodiments, data store 120 may include fixed or removable hard disk drives, flash memory devices, and CD-ROM (compact disc read-only-memory), DVD-ROM (digital versatile disc-ROM), Blu-ray, HD-DVD (high definition DVD), or other magnetic, optical, or solid state storage devices. Data store 120 can be a network attached storage (NAS) and/or a storage area-network (SAN). Although shown as accessible over network 130, in various embodiments, the machine learning server 110 or computing device 140 can include the data store 120.

FIG. 2 is a more detailed illustration of data collector engine 118 of FIG. 1, according to various embodiments. As shown, data collector engine 118 includes a geometric analyzer 204, CAD data 206 and a geometric prompt generator 208. In operation, data collector engine 118 receives a set of CAD models 202 from data store 120 of FIG. 1 or some other storage. Geometric analyzer 204 analyzes the geometry of received CAD models 202 and executes specialized functions to extract geometric information from CAD models 202. Geometric analyzer 204 subsequently generates CAD data 206 using the geometric information extracted from the CAD models 202.

In various embodiments, CAD data 206 comprises DSL commands. These commands are similar to the commands used to generate different shapes in conventional CAD applications. An exemplar sequence of CAD data 206 produced by geometric analyzer 204 is as follows:
POLY_ARC_LINE_LOOP
POINT 12 0
LINE 51 0
LINE 51 37
. . .
EOL
SINGLE_CIRCLE_LOOP
POINT 32 28
RADIUS 28
EOS

In some embodiments, geometric analyzer 204 generates CAD data 206 from CAD models 202 based on non-geometric information. Examples of non-geometric information include ports and loads, where a port is the location of a force exerted on a model or object geometry, and a load is the magnitude, direction, and state of a force exerted on a model or object geometry. In such cases, geometry analyzer 204 generates CAD data based on the force exerted on a model or object and the characteristics of that force.

In various embodiments, CAD models 202 comprise two-dimensional planar sections of solid models or objects. In such cases, the geometric information extracted from the CAD models 202 may include, without limitation:
Outer bounding box
Symmetries of the profile
Area of the profile
Center of gravity of the profile
Centers of circular loops
Bounding boxes of inner poly-arc-line loops
Number of edges in the profile
Number of loops in the profile
Number of vertices which are tangent continuous
Moments of inertia
Medial axis topological graph
   Minimum radius of any maximal disk giving rise to an edge
   Maximum radius of any maximal disk giving rise to an edge
   Average radius of any maximal disk giving rise to an edge
Keepins and Keepouts
Circumference to area ratio
Skeleton graph
Radii of inner circle loops
For an inner circle loop, distances from center point of circle to closest point on any loop in a profile
Minimum distance between any two loops in a profile
Minimum thickness

In other embodiments, CAD models 202 may comprise three-dimensional boundary representation models (“B-Rep”). In such cases, the geometric information extracted from the CAD models 202 may include, without limitation:
The locations and types of 3D holes.
Information about which holes are aligned with other holes in the assembly.
The topological graph connecting the touching faces
3D bounding box.
Number of faces in the B-Rep
Volume
Surface area to volume ratio
Genus (i.e., number of holes running through the solid volume)
Euler characteristic. C=num_vertices-num_edges+num_faces
Locations of holes into planar faces
The types of holes
   Simple hole
   Blind hole
   Through hole
   Counter bore hole
   Counter sink hole
Bolt holes
Fraction of edges with a given convexity
   Sharp-convex
   Sharp-concave
   Tangent plane continuous.
Fraction of the total edge length with a given edge convexity
Fraction of surfaces that are planar.
Fraction of the surface area of the B-Rep that consists of planar faces.
Fraction of surfaces that are singly curved.
Fraction of the surface area that consists of faces that are singly curved.
Fraction of surfaces that are doubly curved.
Fraction of the surface area that consists of faces that are doubly curved
Fraction of surfaces that are free-form.
Fraction of the surface area that consists of faces that are free-form

Geometric prompt generator 208 generates a sequence of geometric prompts 210 based on CAD data 206. More specifically, geometric prompt generator 208 executes functions to convert CAD data 206 to geometric prompts using geometric information included in CAD data 206. Geometric prompt generator 208 can implement any technical feasible approach in determining what geometric prompts correspond to CAD data 206. Geometric prompt generator 208 starts and ends the sequence of geometric prompts 210 with a prefix and suffix to inform model trainer 116 when a specific CAD model sequence begins and ends. “SOS” is an exemplar prefix with which geometric prompt generator 208 may start a given sequence of geometric prompts 210, and “EOC” is an exemplar suffix with which geometric prompt generator 206 may end a given sequence of geometric prompts 210. In some embodiments, geometric prompt generator 208 chooses the order of the different geometric prompts 210 in a given sequence. An exemplar sequence of geometric prompts 208 produced by geometric prompt generator 208 is as follows:
SOS.
MIRROR_Y
AREA_PROFILE 12/16
COG_PROFILE
POINT 32 28
HOLE_CENTER
POINT 32 7
COMPLEXITY_PROFILE 12/16.
NUM_LOOPS 2
TANGENT_CONTINUITY 0/16
BBOX_OUTER
POINT 12 0
POINT 51 63
EOC

As previously described above in conjunction with FIG. 1, model trainer 116 uses the geometric prompts 210 and CAD data 206 generated by data collector engine 118 as training data in order to train CAD data generator 148.

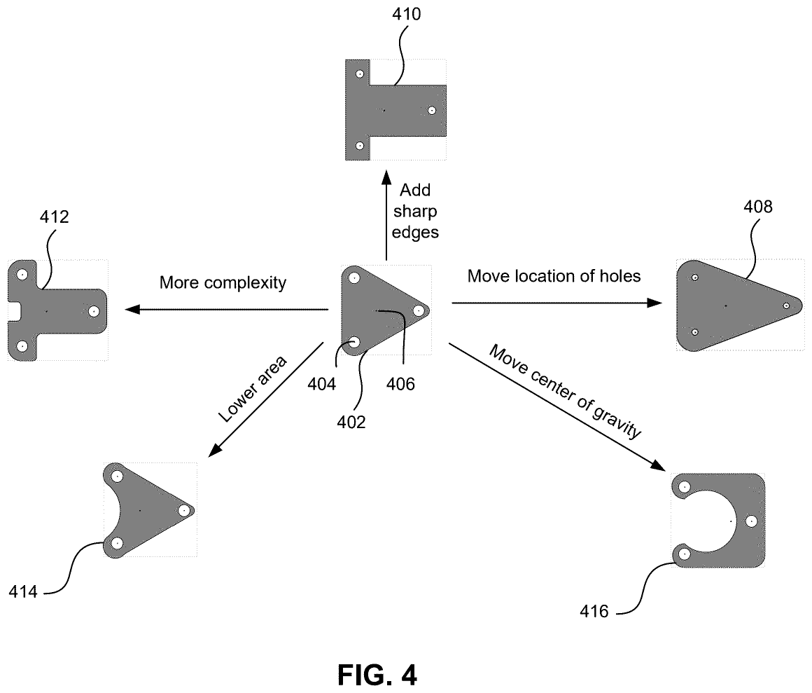

FIG. 3 is a more detailed illustration of CAD generation application 146 of FIG. 1, according to various embodiments. As shown, CAD generation application 146 includes a token representation generator 304, geometric prompts 306, a trained CAD data generator 308, CAD data 310, and a CAD geometry generator 312. In operation, CAD generation application 146 receives control parameters 302 from a user via a user interface (not shown). The control parameters 302 are input into token representation generator 304, which executes functions on the control parameters 302 to convert control parameters 302 to geometric prompts 306. Examples of different control parameters 302 that can be input into the user interface associated with CAD generation application 146 are provided below in conjunction with FIG. 4.

Token representation generator 304 starts and ends the sequence of generated geometric prompts 306 with a prefix and suffix to inform trained CAD data generator 308 when a specific CAD model sequence begins and ends. “SOS” is an exemplar prefix with which token representation generator 304 may start a given sequence of geometric prompts 306, and “EOC” is an exemplar suffix with which token representation generator 304 may end a given sequence of geometric prompts 306.

Trained CAD data generator 308 is trained to map geometric prompts 306 to CAD data 310. Accordingly, upon receiving geometric prompts 306 from the token representation generator 304, trained CAD data generator 308 applies model parameters computed during training to those geometric prompts 306 to generate CAD data 310. As previously described above, in various embodiments, the CAD data 310 generated by trained CAD data generator 308 comprises DSL commands. However, in other embodiments, CAD data 310 can take other forms. In the other embodiments, CAD data 310 may comprise any sequence of text data, and trained CAD data generator 308 may be any type of machine-learning model that is capable of receiving a sequence of text inputs and generating a sequence of text outputs.

Trained CAD data generator 308 ends the sequence of generated CAD data 310 with a suffix to inform CAD geometry generator 312 when a given sequence of CAD data 310 ends. “EOS” is an exemplar suffix with which trained CAD data generator 308 may end a given sequence of CAD data 310.

CAD geometry generator 312 receives CAD data 310 output from the trained CAD data generator 308 and generates CAD model(s) 314 based on CAD data 310. More specifically, CAD geometry generator 312 executes one or more drawing functions on CAD data 310 to draw one or more visual representations based on CAD data 310. In various embodiments where CAD data 310 comprises DSL commands, the drawing functions executed by geometry generator 312 read the DSL commands line by line and draw a visual representation for each DSL command. The resulting visual representations comprise CAD model(s) 314. A file having a DWG extension is an example of the file format for CAD model(s) 314. Geometry generator 312 terminates execution of the drawing functions upon reading the “EOS” suffix included at the end of a sequence of CAD data 310.

In some embodiments CAD generation application 146 generates new CAD models 314 in real-time, in response to a user modifying one or more control parameters 302 input into the user interface (not shown) associated with CAD generation application 146. For example, if a user moves the center of gravity in the user interface, then CAD generation application 146 generates a new CAD model 314 with a new appearance and displays the new CAD model 314 to the user. Examples of how changes to the control parameters 302 input into the user interface can change the appearance of a CAD model 314 generated by CAD generation application 146 are provided below in conjunction with FIG. 4.

FIG. 4 illustrates different exemplary CAD models that can be generated by CAD generation application 146 of FIG. 1, according to various embodiments. To produce CAD model 402, a user can input certain control parameters, such as the location of holes 404, center of gravity 406, and other control parameters like area, complexity and, tangent continuity (collectively, the “initial control parameters”), into a user interface (not shown) associated with CAD generation application 146. In response to receiving the control parameters, CAD generation application 146 generates CAD model 402, as described above in conjunction with FIG. 3. Notably, by modifying the initial control parameters and/or inputting different control parameters into the user interface, CAD model 402 can be modified, or a completely new CAD model can be generated. Some simplified examples are as follows.

When the vertical separation of the holes 404 is changed from 0.5 to 0.3 model units (along with a corresponding change to the height of the bounding box), CAD generation application 146 generates CAD model 408, where the hole locations are different from the hole locations in CAD model 402. Moving counter-clockwise around FIG. 4, when the tangent continuity control parameter is decreased from 15 to 0, CAD generation application 146 generates CAD model 410, which has sharper edges than CAD model 402. When the complexity control parameter is increased from 2 to 7, CAD generation application 146 generates CAD model 412, which is more complex than CAD model 402. When the area control parameter is decreased from 7 to 4, CAD generation application generates CAD model 414, which occupies a smaller area than CAD model 402. Finally, when the center of gravity 406 is moved to the right by 0.2 model units, CAD generation application 146 generates CAD model 416, where the center of gravity is different from the center of gravity of CAD model 402.

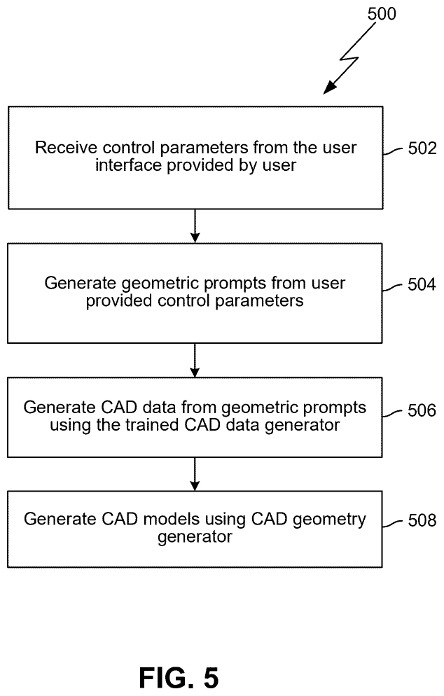

FIG. 5 is a flow diagram of method steps for generating CAD models 314, according to various embodiments. Although the method steps are described in conjunction with the systems of FIGS. 1-4, persons skilled in the art will understand that any system configured to perform the method steps in any order falls within the scope of the various embodiments.

As shown, a method 500 begins at step 502, where CAD generation application 146 receives control parameters 302 from the user interface provided by user. Examples of different control parameters 302 that can be input into the user interface associated with CAD generation application 146 are provided above in conjunction with FIG. 4.

At step 504, CAD generation application 146 generates geometric prompts 306 from user provided control parameters 302. More specifically, the control parameters 302 are input to token representation generator 304, which executes functions on control parameters 302 to convert control parameters 302 to geometric prompts 306. Token representation generator 304 starts and ends the sequence of generated geometric prompts 306 with a prefix and suffix to inform trained CAD data generator 308 when a specific CAD model sequence begins and ends. “SOS” is an exemplar prefix with which token representation generator 304 may start a given sequence of geometric prompts 306, and “EOC” is an exemplar suffix with which token representation generator 304 may end a given sequence of geometric prompts 306.

At step 506, CAD generation application 146 generates CAD data 310 from geometric prompts 306 using the trained CAD data generator 308. In this regard, upon receiving geometric prompts 306 from the token representation generator 304, trained CAD data generator 308 applies model parameters computed during training to those geometric prompts 306 to generate CAD data 310. As previously described above, in various embodiments, the CAD data 310 generated by trained CAD data generator 308 comprises DSL commands. However, in other embodiments, CAD data 310 can take other forms. In the other embodiments, CAD data 310 may comprise any sequence of text data, and trained CAD data generator 308 may be any type of machine-learning model that is capable of receiving a sequence of text inputs and generating a sequence of text outputs. Trained CAD data generator 308 ends the sequence of generated CAD data 310 with a suffix to inform CAD geometry generator 312 when a given sequence of CAD data 310 ends. “EOS” is an exemplar suffix with which trained CAD data generator 308 may end a given sequence of CAD data 310.

At step 508, CAD generation application 146 generates CAD models 314 using CAD geometry generator 312. More specifically, CAD geometry generator 312 receives CAD data 310 output from the trained CAD data generator 308 and generates CAD model(s) 314 based on CAD data 310. In so doing, CAD geometry generator 312 executes one or more drawing functions on CAD data 310 to draw one or more visual representations based on CAD data 310. In various embodiments where CAD data 310 comprises DSL commands, the drawing functions executed by geometry generator 312 read the DSL commands line by line and draw a visual representation for each DSL command. The resulting visual representations comprise CAD model(s) 314. Geometry generator 312 terminates execution of the drawing functions upon reading the “EOS” suffix included at the end of a sequence of CAD data 310.

FIG. 6 is a flow diagram of method steps for training CAD data generator 148, according to various embodiments. Although the method steps are described in conjunction with the systems of FIGS. 1-4, persons skilled in the art will understand that any system configured to perform the method steps in any order falls within the scope of the various embodiments.

As shown, a method 600 begins at step 602, where data collector engine 118 receives CAD models 202 from data store 120. In various embodiments, data collector engine 118 may receive CAD models 202 from other data storage systems, like a cloud storage, NAS drive, or a network storage connected to the machine learning server 110.

At step 604, data collector engine 118 generates associated CAD data 206 and associated geometric prompts 210 for each received CAD model 202. Data collector engine 118 first generates associated CAD data 206 by analyzing the geometry of each received CAD model 202 and then determines what geometric prompts 210 correspond to the generated CAD data 206. More specifically, geometric prompt generator 208 executes functions to convert CAD data 206 to associated geometric prompts 210 using geometric information included in CAD data 206. The operations invoked by data collector engine 118 when generating training data are discussed in greater detail above in conjunction with FIG. 2.

At step 606, model trainer 116 performs training operations to train CAD data generator 148 using CAD data 206 and associated geometric prompts 210 received from data collector engine 118. In operation, model trainer 116 can dynamically adjust training parameters and methodologies by incorporating a feedback loop that leverages real-time analysis of any performance metric, such as precision, recall, and loss functions. More generally, model trainer 116 can implement any technically feasible training operations when training CAD data generator 306.

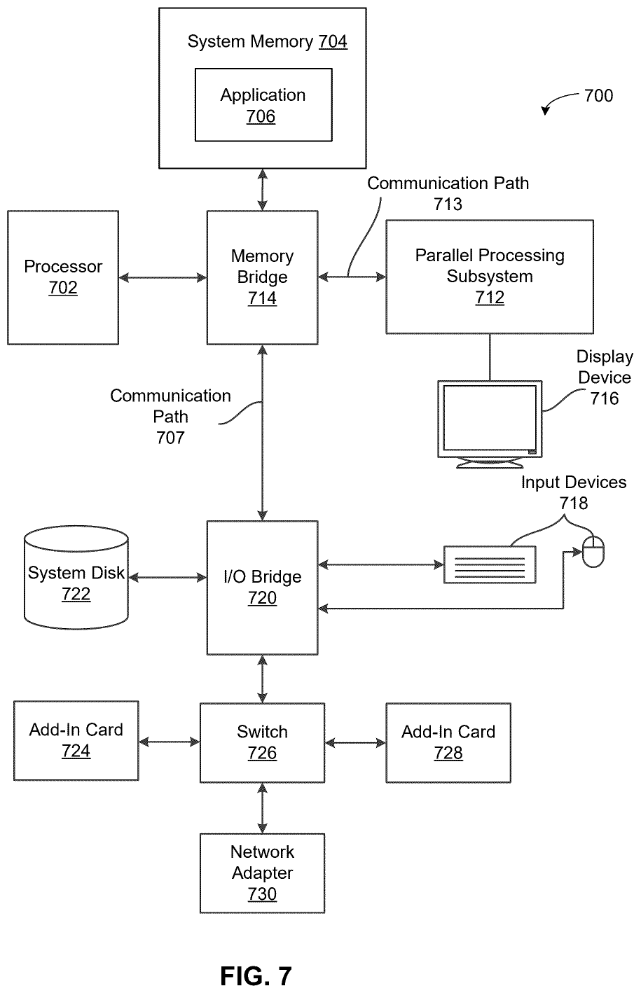

FIG. 7 is a block diagram illustrating a computing device 700 configured to implement one or more aspects of the various embodiments. Computing device 700 may be any type of computing device, including, without limitation, a server machine, a server platform, a desktop machine, a laptop machine, a hand-held/mobile device, a digital kiosk, an in-vehicle infotainment system, and/or a wearable device. In some embodiments, computing device 700 is a server machine operating in a data center or a cloud computing environment that provides scalable computing resources as a service over a network.

As shown, the computing device 700 includes, without limitation, the processor(s) 702 and the memory(ies) 704 coupled to a parallel processing subsystem 712 via a memory bridge 714 and a communication path 713. Memory bridge 714 is further coupled to an I/O (input/output) bridge 720 via a communication path 707, and I/O bridge 720 is, in turn, coupled to a switch 726.

In various embodiments, I/O bridge 720 is configured to receive user input information from optional input devices 718, such as a keyboard, mouse, touch screen, sensor data analysis (e.g., evaluating gestures, speech, or other information about one or more uses in a field of view or sensory field of one or more sensors), and/or the like, and forward the input information to the processor(s) 702 for processing. In some embodiments, the computing device 700 may be a server machine in a cloud computing environment. In such embodiments, computing device 700 may not include input devices 718, but may receive equivalent input information by receiving commands (e.g., responsive to one or more inputs from a remote computing device) in the form of messages transmitted over a network and received via the network adapter 730. In some embodiments, switch 726 is configured to provide connections between I/O bridge 720 and other components of the computing device 700, such as a network adapter 730 and various add-in cards 724 and 728.

In some embodiments, I/O bridge 720 is coupled to a system disk 722 that may be configured to store content and applications and data for use by processor(s) 702 and parallel processing subsystem 712. In one embodiment, system disk 722 provides non-volatile storage for applications and data and may include fixed or removable hard disk drives, flash memory devices, and CD-ROM (compact disc read-only-memory), DVD-ROM (digital versatile disc-ROM), Blu-ray, HD-DVD (high-definition DVD), or other magnetic, optical, or solid state storage devices. In various embodiments, other components, such as universal serial bus or other port connections, compact disc drives, digital versatile disc drives, film recording devices, and the like, may be connected to I/O bridge 720 as well.

In various embodiments, memory bridge 714 may be a Northbridge chip, and I/O bridge 720 may be a Southbridge chip. In addition, communication paths 707 and 713, as well as other communication paths within computing device 700, may be implemented using any technically suitable protocols, including, without limitation, AGP (Accelerated Graphics Port), HyperTransport, or any other bus or point-to-point communication protocol known in the art.

In some embodiments, parallel processing subsystem 712 comprises a graphics subsystem that delivers pixels to an optional display device 716 that may be any conventional cathode ray tube, liquid crystal display, light-emitting diode display, and/or the like. In such embodiments, the parallel processing subsystem 712 may incorporate circuitry optimized for graphics and video processing, including, for example, video output circuitry. Such circuitry may be incorporated across one or more parallel processing units (PPUs), also referred to herein as parallel processors, included within the parallel processing subsystem 712.

In some embodiments, the parallel processing subsystem 712 incorporates circuitry optimized (e.g., that undergoes optimization) for general purpose and/or compute processing. Again, such circuitry may be incorporated across one or more PPUs included within parallel processing subsystem 712 that are configured to perform such general purpose and/or compute operations. In yet other embodiments, the one or more PPUs included within parallel processing subsystem 712 may be configured to perform graphics processing, general purpose processing, and/or compute processing operations. System memory 704 includes at least one device driver configured to manage the processing operations of the one or more PPUs within parallel processing subsystem 712. In addition, system memory 704 includes application 706. When computing device 700 is implemented as machine learning server 110, application 706 comprises model trainer 116 and data collector engine 118. When computing device 700 is implemented as computing device 140, application 706 comprises CAD generation application 146.

In various embodiments, parallel processing subsystem 712 may be integrated with one or more of the other elements of FIG. 7 to form a single system. For example, parallel processing subsystem 712 may be integrated with processor 702 and other connection circuitry on a single chip to form a system on a chip (SoC).

In some embodiments, communication path 713 is a PCI Express link, in which dedicated lanes are allocated to each PPU. Other communication paths may also be used. The PPU advantageously implements a highly parallel processing architecture, and the PPU may be provided with any amount of local parallel processing memory (PP memory).

It will be appreciated that the system shown herein is illustrative and that variations and modifications are possible. The connection topology, including the number and arrangement of bridges, the number of CPUs 702, and the number of parallel processing subsystems 712, may be modified as desired. For example, in some embodiments, system memory 704 could be connected to the processor(s) 702 directly rather than through memory bridge 714, and other devices may communicate with system memory 704 via memory bridge 714 and processor 702. In other embodiments, parallel processing subsystem 712 may be connected to I/O bridge 720 or directly to processor 702, rather than to memory bridge 714. In still other embodiments, I/O bridge 720 and memory bridge 714 may be integrated into a single chip instead of existing as one or more discrete devices. In certain embodiments, one or more components shown in FIG. 7 may not be present. For example, switch 726 could be eliminated, and network adapter 730 and add-in cards 724, 728 would connect directly to I/O bridge 720. Lastly, in certain embodiments, one or more components shown in FIG. 7 may be implemented as virtualized resources in a virtual computing environment, such as a cloud computing environment. In particular, the parallel processing subsystem 712 may be implemented as a virtualized parallel processing subsystem in at least one embodiment. For example, the parallel processing subsystem 712 may be implemented as a virtual graphics processing unit(s) (vGPU(s)) that renders graphics on a virtual machine(s) (VM(s)) executing on a server machine(s) whose GPU(s) and other physical resources are shared across one or more VMs.

In sum, an approach for generating CAD models using geometric prompts has been described. A geometric prompt includes the information a designer would like to use for generating a shape. Examples of geometric prompts can be, without limitation, a hole location, center of gravity, and bounding box having a certain shape. In the described approach, a generative machine learning model is trained to consume a sequence of geometric prompts and generate output CAD data in the form of Domain Specific Language (DSL) commands. These commands are similar to the commands used to generate different shapes in conventional CAD applications. In some implementations, an autoregressive method may be used, such as decoder-only transformer, to generate the output CAD data. In other implementations, a transformer encoder may be used to encode the geometric prompts and feed the encoded prompts to a diffusion model via cross-attention to generate the output CAD data. Specialized functions are then executed on the CAD data output by the generative machine learning model to generate CAD models automatically from the CAD output data.

At run-time, the user inputs control parameters into the user interface that help define the shape the user wants to generate. A token representation generator converts control parameters provided by the user into geometric prompts. In other embodiments, stick models representing linkage designs and assembly interface specifications may be used to define the geometric prompts. The trained generative machine learning model converts the geometric prompts into DSL commands. Specialized functions included in a CAD geometry generator are then executed on the DSL commands output by the trained genitive machine learning model to generate a CAD model based on the DSL commands. With this approach, the user can control the CAD model generation process by modifying control parameters that are input into the user interface.

On the training side, a set of shapes and corresponding geometric prompts are used to train the generative machine learning model. The generative machine learning model learns the relationship between the training data and the output CAD data. To generate the training data, different shapes are analyzed by geometric functions, and the geometric functions generate geometric prompts corresponding to each analyzed shape.

One technical advantage of the disclosed techniques relative to the prior art is that the disclosed techniques can substantially facilitate the overall process of designing CAD objects and CAD models of differing levels of complexity, thereby increasing the accessibility of CAD software and applications to a wider array of users with differing skill sets. With the disclosed technique, users can express complex CAD object or CAD models using a few simple control parameters without having to learn the intricacies of CAD software or a CAD application. Another technical advantage of the disclosed techniques is that the disclosed techniques leverage a machine learning model that is trained using a vast number of previous CAD objects and CAD models. The trained model is able to generate the commands associated with optimized and creative CAD objects and CAD models from a few simple control parameters, which removes the burdens of the conventional design process and conventional CAD software and applications from users. These technical advantages provide one or more technological improvements over prior art approaches.

1. In some embodiments, a computer-implemented method for generating computer-aided design (CAD) models comprises generating a plurality of geometric prompts based on a plurality of inputs, executing a trained machine-learning model on the geometric prompts to generate CAD data, and generating at least one CAD model based on the CAD data.

2. The computer-implemented method of clause 1, wherein generating a plurality of geometric prompts comprising executing one or more functions on the plurality of inputs to convert the plurality of inputs into the plurality of geometric prompts.

3. The computer-implemented method of clauses 1 or 2, wherein the plurality of geometric prompts includes a prefix that designates a beginning of the plurality of geometric prompts and a suffix that designates an ending of the plurality of geometric prompts.

4. The computer-implemented method of any of clauses 1-3, wherein generating at least one CAD model comprises executing one or more drawing functions on the CAD data.

5. The computer-implemented method of any of clauses 1-4, wherein the CAD data comprises domain specific language commands.

6. The computer-implemented method of any of clauses 1-5, wherein executing the trained machine-learning model on the geometric prompts to generate the CAD data comprises passing the geometric prompts to an encoder to generate a plurality of tokens, and passing the plurality of tokens to a decoder to generate the CAD data via cross attention.

7. The computer-implemented method of any of clauses 1-6, further comprising receiving a set of CAD models, generating associated CAD data for the set of CAD models, and generating a set of geometric prompts based on the associated CAD data.

8. The computer-implemented method of any of clauses 1-7, further comprising training an untrained machine-learning model using the associated CAD data and the set of geometric prompts.

9. The computer-implemented method of any of clauses 1-8, wherein training the untrained machine learning model comprises inputting the set of geometric prompts into the untrained machine learning model to generate intermediate CAD data, computing one or more losses based on the intermediate CAD data and ground truth CAD data, and updating the untrained machine-learning model based on the one or more losses.

10. The computer-implemented method of any of clauses 1-9, wherein generating the set of geometric prompts comprises executing one or more geometric functions on each CAD model included in the set of CAD models to analyze a geometry associated with the CAD model.

11. The computer-implemented method of any of clauses 1-10, wherein the plurality of inputs received via the user interface comprises a plurality of control parameters.

12. The computer-implemented method of any of clauses 1-11, wherein the at least one CAD model comprises a two-dimensional CAD profile or a three-dimensional boundary representation model.

13. The computer-implemented method of any of clauses 1-12, further comprising receiving the plurality of inputs via a user interface.

14. The computer-implemented method of any of clauses 1-13, wherein the plurality of inputs is associated with at least one stick model representation of a linkage or at least one assembly interface specification.

15. In some embodiments, one or more non-transitory computer-readable media include instructions that, when executed by one or more processors, cause the one or more processors to perform that steps of receiving a plurality of inputs via a user interface, generating a plurality of geometric prompts based on the plurality of inputs, executing a trained machine-learning model on the geometric prompts to generate CAD data, and generating at least one CAD model based on the CAD data.

16. The one or more non-transitory computer-readable media of clause 15, wherein the plurality of control parameters includes at least one of a center of gravity, a bounding box, or a hole location.

17. The one or more non-transitory computer-readable media of clauses 15 or 16, wherein a data collector engine generates CAD data and a set of geometric prompts based on one or more stored CAD models, wherein the CAD data and set of geometric prompts are used to train a CAD data generator.

18. The one or more non-transitory computer-readable media of any of clauses 15-17, wherein a CAD generation application includes a trained CAD data generator that generates CAD data based on geometric prompts, wherein control parameters received by the CAD application program are converted into the geometric prompts.

19. The one or more non-transitory computer-readable media of any of clauses 15-18, wherein generating a plurality of geometric prompts comprising executing one or more functions on the plurality of inputs to convert the plurality of inputs into the plurality of geometric prompts.

20. The one or more non-transitory computer-readable media of any of clauses 15-19, wherein the plurality of geometric prompts includes a prefix that designates a beginning of the plurality of geometric prompts and a suffix that designates an ending of the plurality of geometric prompts.

21. The one or more non-transitory computer-readable media of any of clauses 15-20, wherein the CAD data comprises domain specific language commands, and generating at least one CAD model comprises executing one or more drawing functions on the domain specific language commands.

22. The one or more non-transitory computer-readable media of any of clauses 15-21, further comprising receiving a set of CAD models, generating associated CAD data for the set of CAD models, and generating a set of geometric prompts based on the associated CAD data.

23. The one or more non-transitory computer-readable media of any of clauses 15-22, further comprising training an untrained machine-learning model using the associated CAD data and the set of geometric prompts.

24. In some embodiments, a computer system comprises one or more memories that include instructions, and one or more processors that are coupled to the one or more memories and, when executing the instructions, are configured to perform the steps of receiving a plurality of inputs via a user interface, generating a plurality of geometric prompts based on the plurality of inputs, executing a trained machine-learning model on the geometric prompts to generate CAD data, and generating at least one CAD model based on the CAD data.

Any and all combinations of any of the claim elements recited in any of the claims and/or any elements described in this application, in any fashion, fall within the contemplated scope of the present disclosure and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

Aspects of the present embodiments may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “module” or “system.” Furthermore, aspects of the present disclosure may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors may be, without limitation, general purpose processors, special-purpose processors, application-specific processors, or field-programmable gate arrays.

The flowchart and block diagrams in the figures illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While the preceding is directed to embodiments of the present disclosure, other and further embodiments of the disclosure may be devised without departing from the basic scope thereof, and the scope thereof is determined by the claims that follow.

What is claimed is:

1. A computer-implemented method for generating computer-aided design (CAD) models, the method comprising:
generating a plurality of geometric prompts based on a plurality of inputs;
executing a trained machine-learning model on the geometric prompts to generate CAD data; and
generating at least one CAD model based on the CAD data.

2. The computer-implemented method of claim 1, wherein generating a plurality of geometric prompts comprising executing one or more functions on the plurality of inputs to convert the plurality of inputs into the plurality of geometric prompts.

3. The computer-implemented method of claim 2, wherein the plurality of geometric prompts includes a prefix that designates a beginning of the plurality of geometric prompts and a suffix that designates an ending of the plurality of geometric prompts.

4. The computer-implemented method of claim 1, wherein generating at least one CAD model comprises executing one or more drawing functions on the CAD data.

5. The computer-implemented method of claim 4, wherein the CAD data comprises domain specific language commands.

6. The computer-implemented method of claim 1, wherein executing the trained machine-learning model on the geometric prompts to generate the CAD data comprises passing the geometric prompts to an encoder to generate a plurality of tokens, and passing the plurality of tokens to a decoder to generate the CAD data via cross attention.

7. The computer-implemented method of claim 1, further comprising:
receiving a set of CAD models;
generating associated CAD data for the set of CAD models; and
generating a set of geometric prompts based on the associated CAD data.

8. The computer-implemented method of claim 7, further comprising training an untrained machine-learning model using the associated CAD data and the set of geometric prompts.

9. The computer-implemented method of claim 8, wherein training the untrained machine learning model comprises:
inputting the set of geometric prompts into the untrained machine learning model to generate intermediate CAD data;
computing one or more losses based on the intermediate CAD data and ground truth CAD data; and
updating the untrained machine-learning model based on the one or more losses.

10. The computer-implemented of method claim 7, wherein generating the set of geometric prompts comprises executing one or more geometric functions on each CAD model included in the set of CAD models to analyze to analyze a geometry associated with the CAD model.

11. The computer-implemented method of claim 1, wherein the plurality of inputs received via the user interface comprises a plurality of control parameters.

12. The computer-implemented method of claim 1, wherein the at least one CAD model comprises a two-dimensional CAD profile or a three-dimensional boundary representation model.

13. The computer-implemented method of claim 1, further comprising receiving the plurality of inputs via a user interface.

14. The computer-implemented method of claim 1, wherein the plurality of inputs is associated with at least one stick model representation of a linkage or at least one assembly interface specification.

15. One or more non-transitory computer-readable media including instructions that, when executed by one or more processors, cause the one or more processors to perform that steps of:
receiving a plurality of inputs via a user interface;
generating a plurality of geometric prompts based on the plurality of inputs;
executing a trained machine-learning model on the geometric prompts to generate CAD data; and
generating at least one CAD model based on the CAD data.

16. The one or more non-transitory computer-readable media of claim 15, wherein the plurality of control parameters includes at least one of a center of gravity, a bounding box, or a hole location.

17. The one or more non-transitory computer-readable media of claim 15, wherein a data collector engine generates CAD data and a set of geometric prompts based on one or more stored CAD models, wherein the CAD data and set of geometric prompts are used to train a CAD data generator.

18. The one or more non-transitory computer-readable media of claim 15, wherein a CAD generation application includes a trained CAD data generator that generates CAD data based on geometric prompts, wherein control parameters received by the CAD application program are converted into the geometric prompts.

19. The one or more non-transitory computer-readable media of claim 15, wherein generating a plurality of geometric prompts comprising executing one or more functions on the plurality of inputs to convert the plurality of inputs into the plurality of geometric prompts.

20. The one or more non-transitory computer-readable media of claim 19, wherein the plurality of geometric prompts includes a prefix that designates a beginning of the plurality of geometric prompts and a suffix that designates an ending of the plurality of geometric prompts.

21. The one or more non-transitory computer-readable media of claim 15, wherein the CAD data comprises domain specific language commands, and generating at least one CAD model comprises executing one or more drawing functions on the domain specific language commands.

22. The one or more non-transitory computer-readable media of claim 15, further comprising:
receiving a set of CAD models;
generating associated CAD data for the set of CAD models; and
generating a set of geometric prompts based on the associated CAD data.

23. The one or more non-transitory computer-readable media of claim 22, further comprising training an untrained machine-learning model using the associated CAD data and the set of geometric prompts.

24. A computer system, comprising:
one or more memories that include instructions; and
one or more processors that are coupled to the one or more memories and, when executing the instructions, are configured to perform the steps of:
receiving a plurality of inputs via a user interface;
generating a plurality of geometric prompts based on the plurality of inputs;
executing a trained machine-learning model on the geometric prompts to generate CAD data; and
generating at least one CAD model based on the CAD data.
